(19) United States
(12) Patent Application Publication
(10) Pub. No.: US 2023/0420586 A1
(43) Pub. Date: Dec. 28, 2023

(54) PHOTODIODE WITH HIGH POWER CONVERSION EFFICIENCY AND POSITIVE TEMPERATURE COEFFICIENT

(71) Applicant: SLT Technologies, Inc., Los Angeles, CA (US)

(72) Inventors: Islam SAYED, Goleta, CA (US); Sang Ho OH, Goleta, CA (US); Nathan YOUNG, Goleta, CA (US); Drew W. CARDWELL, Rainier, WA (US); Mark P. D'EVELYN, Vancouver, WA (US)

(21) Appl. No.: 18/342,617

(22) Filed: Jun. 27, 2023

Related U.S. Application Data
(60) Provisional application No. 63/500,862, filed on May 8, 2023.
(60) Provisional application No. 63/356,231, filed on Jun. 28, 2022.

(51) Int. Cl. H01L 31/0352; H01L 31/0224; H01L 31/0232; H01L 31/0304; H01L 31/0236; H01L 31/109; H01L 31/18

(52) U.S. Cl. CPC H01L 31/035236; H01L 31/022408; H01L 31/02327; H01L 31/03048; H01L 31/02363; H01L 31/109; H01L 31/1848

(57) ABSTRACT

According to the present disclosure, techniques related to manufacturing and applications of power photodiode structures and devices based on group-III metal nitride and gallium-based substrates are provided. More specifically, embodiments of the disclosure include techniques for fabricating photodiode devices comprising one or more of GaN, AlN, InN, InGaN, AlGaN, and AlInGaN, structures and devices. Such structures or devices can be used for a variety of applications including optoelectronic devices, photodiodes, power-over-fiber receivers, and others.

### CROSS-REFERENCE TO RELATED APPLICATION

This patent application claims the benefit of U.S. Provisional Patent Application No. 63/356,231, filed Jun. 28, 2022, and U.S. Provisional Patent Application No. 63/500,862, filed May 8, 2023, each of which is incorporated by reference herein.

### BACKGROUND

### Field

This disclosure relates generally to nitride-based photodiodes for conversion of light energy to electrical power, particularly at high light and current densities, and methods for fabrication. The invention can be applied to applications involving conversion of light energy to electrical energy, particularly via optical fibers, other optoelectronic devices, and similar products.

### Description of the Related Art

Electrical power is typically transmitted over a wire, for example, a copper wire. However, such wires can be heavy, cumbersome, and expensive, and the transmitted power can be subject to electromagnetic interference. Some of these limitations can be overcome by transmitting power over an optical fiber. However, unfortunately, with current conventional designs such approaches are not yet commercially viable. In addition, current approaches generally involve light at infrared wavelengths, which has certain disadvantages over visible light, or visible optical radiation, such as greater sensitivity to temperature variations in the surrounding environment.

Gallium nitride (GaN) based optoelectronic and electronic devices are of tremendous commercial importance. The best-developed of these devices include light emitting diodes (LEDs) and laser diodes, and GaN-based power diodes and transistors are becoming increasingly important. There is also interest in emerging applications. De Santi, and coauthors [Materials 11, 153 (2018)] described an application whereby electrical power is converted to optical power using a laser diode, the optical power is coupled to an optical fiber and transmitted to a remote location, then the optical power is converted back to electrical power using a photodiode. Both the laser diode and the photodiode were based on GaN-on-sapphire devices and the system performance was relatively poor. The photodiode was a particular challenge, with a reported efficiency of 17%. GaN-based solar cells have also been reported by a number of groups, typically utilizing GaN-on-sapphire structures for low power (ca. one sun) applications. Even concentrator solar cell structures, which are well known in the art for other materials systems, are only able to generate substantially lower current densities than those that are the principal focus of the current invention.

Related applications have been disclosed using GaAs-based lasers and photodiodes, at wavelengths in the near-infrared. However, due to its larger bandgap, photodiodes based on the nitrides should enable considerably higher open-circuit voltages and superior efficiencies at elevated temperatures and at high input power levels, relative to corresponding GaAs-based devices and systems.

Recently, Cardwell and D'Evelyn [US 2021/0020798, US 2021/0167231] have disclosed a number of embodiments of nitride-based photodiode structures, devices, and optical systems. The performance of nitride photodiode with Indium, Gallium, Nitride (InGaN) absorber layers can suffer from strain-induced defect generation, especially for relatively thick absorber layers or relatively high In concentrations. Such defects can reduce the external quantum efficiency, fill factor, and open circuit voltage of the photodiode. Under monochromatic illumination, the power conversion efficiency (PCE) can be expressed as a product of the zero-bias external quantum efficiency (EQE), the fill factor (FF), and eV_{oc}/hν, where V_{oc} represents the open circuit voltage, e represents the electron charge, and hν represents the photon energy. Further improvements are highly desirable.

### SUMMARY

In an example, the present invention provides a photodiode device. The optical device has a gallium and nitrogen containing substrate member having a backside surface and an upper surface. The device has an N-type gallium and nitrogen containing material having a silicon dopant overlying the upper surface, the N-type gallium and nitrogen containing material being configured as a buffer material. In an example, the buffer material has a thickness ranging from about 0.5 micrometer to one and a half micrometer. The device has a superlattice (SL) indium gallium nitrogen containing material overlying the N-type gallium and nitrogen containing material. The superlattice comprises a plurality of indium gallium nitrogen containing material layers and gallium and nitrogen containing material layers. The superlattice is a periodic structure that has twenty-five to eighty indium gallium nitrogen containing material layers and gallium and nitrogen containing material layers. The device has a lower barrier (LB) indium gallium nitrogen containing material overlying the SL indium gallium nitrogen containing material. The LB material has an indium concentration ranging from zero to four percent. The LB material has a thickness ranging from 6 to 14 nanometers. In an example, the device has a plurality of quantum well regions ranging from 30 to 50 quantum wells overlying the LB indium gallium nitrogen containing material. Each of the quantum wells has an indium gallium nitride material having a thickness of 2.0 nanometers to 4.0 nanometers, and an indium concentration ranging from ten percent to 14 percent, and a gallium nitride material having a thickness of 1.0 nanometers to 2.5 nanometers. In an example, the plurality of quantum well regions is in an undoped state. The device has an upper barrier layer, including indium gallium nitrogen containing material overlying the plurality of quantum well regions. The indium gallium nitride in the upper barrier layer has a concentration ranging from zero to four percent, and a thickness of 4 nanometers to 10 nanometers. In an example, the upper barrier material is in an undoped state. The device has an upper cladding layer, including gallium nitrogen containing material overlying the upper barrier layer. The upper cladding layer gallium and nitrogen containing material comprises a magnesium dopant material having a concentration 8×10¹⁹ atoms/cm³ to 6×10²⁰ atoms/cm³, and a thickness of sixteen nanometers to twenty-four nanometers. The device has a P-type gallium and nitrogen containing material overlying the upper cladding layer indium, gallium, and nitrogen containing material. The P-type material is a cap material. In an example, the device has a P-type contact comprises gallium and nitrogen material having a magnesium dopant material. In an example, the P-type contact is in electrical and physical contact with the P-type gallium and nitrogen containing material.

In an example, the present invention provides a photodiode device. The device has a gallium and nitrogen containing substrate member having a backside surface and an upper surface. The device has an absorber layer comprising a plurality of quantum well regions overlying the upper surface. The device has a plurality of hexagonal shaped pyramid structures spatially disposed along the backside surface. In an example, each of the hexagonal shaped pyramid structures has a height ranging from about 0.3 micrometer to about 30 micrometers, and a base ranging from about 0.3 micrometer to 30 micrometer. In an example, each of the hexagonal shaped pyramid structures extends from a crystalline structure of the gallium and nitrogen containing substrate member, and has an irregularity in size ranging from 0% to 50%, but can be others. In an example, the device has an interior region (typically planar in shape) disposed between a pair of the plurality of hexagonal shaped pyramid structures. The device has a plurality of nanodots spatially disposed overlying the interior region and overlying a surface region of each of the hexagonal shaped pyramid structures and configured to direct electromagnetic radiation having a wavelength ranging from 360 to 500 nanometers the absorber layer to increase an absorption of the radiation into the absorber layer, and thereby coupling additional radiation into the absorber layer.

Disclosed herein is a nitride photodiode that, when illuminated with one or more wavelengths between 360 nm and 500 nm at a power density >1 W/cm², has a positive fill factor temperature coefficient in one or more temperature intervals above −50° C., a fill factor >70% at one or more temperatures above −50° C., and a power conversion efficiency >40% at one or more temperatures above −50° C.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a simplified diagram illustrating an illuminated current-voltage curve for a photodiode device, according to an embodiment of the present disclosure.

FIG. 2 is a simplified diagram illustrating a nitride-based power photodiode structure that has been prepared according to an embodiment of the present disclosure.

FIG. 3 is a simplified diagram illustrating a structure for light trapping configured on a photodiode device according to an embodiment of the present disclosure.

FIG. 4 is a simplified diagram illustrating a simple optical cavity that can be used in conjunction with a nitride-based power photodiode, according to an embodiment of the present disclosure.

FIG. 5 is a scanning electron micrograph of a textured region on the backside surface of a nitride-based power photodiode structure that has been prepared according to an embodiment of the present disclosure.

FIG. 6 is a simplified diagram illustrating the illuminated current-voltage behavior of a photodiode according to an embodiment of the present disclosure.

FIG. 7 is a simplified diagram illustrating a process flow for forming nanostructures on a backside surface of a nitride-based power photodiode structure according to an embodiment of the present disclosure.

FIG. 8 is a scanning electron micrograph of nanostructures on a textured region on the backside surface of a nitride-based power photodiode structure that has been prepared according to an embodiment of the present disclosure.

FIG. 9 is a simplified diagram illustrating a fiber-illuminated current-voltage test setup that can be used to measure illuminated current-voltage curves on nitride photodiode chips, according to an embodiment of the present disclosure.

FIG. 10A is a simplified diagram showing illuminated current-voltage curves measured as a function of stage temperature, according to an embodiment of the present disclosure.

FIG. 10B is a simplified diagram showing an enlarged portion of the illuminated current-voltage curves illustrated in FIG. 10A, according to an embodiment of the present disclosure.

FIG. 11 is a simplified diagram showing fill factor (FF), zero-bias external quantum efficiency (EQE), power conversion efficiency (PCE), and (eV_{oc}/hν) as a function of stage temperature, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

According to the present disclosure, techniques related to manufacturing and applications of power photodiode structures and devices based on group-III metal nitride and gallium-based substrates are provided. More specifically, embodiments of the disclosure include techniques for fabricating photodiode devices comprising one or more of GaN, AlN, InN, InGaN, AlGaN, and AlInGaN, structures and devices. Certain aspects of this invention may also extend to other material systems. Such structures or devices can be used for a variety of applications including optoelectronic devices, photodiodes, power-over-fiber receivers, and others.

As noted previously, lasers and photodiodes are better developed in the GaAs material system. One of the key differences in materials properties between the arsenide and nitride systems is that the bandgap may be varied readily with minimal impact on lattice constant in the case of the arsenides, e.g., via AlGaAs, but not in the case of the nitrides. Traditional photodiode package architectures incorporating nitride absorber layers may require an absorber layer thickness on the order of several hundred nanometers to absorb the large majority of the incident light. Assuming an absorber layer absorption coefficient of 1×10⁵ cm⁻¹, the light absorbed in a single pass is approximately 39%, 63%, 87%, 95%, and 98% for thicknesses of 50, 100, 200, 300, and 400 nm, respectively. In the case of the nitrides, such a thickness of InGaN, with sufficient indium (In) to efficiently absorb blue or violet light, may be too strained to avoid relaxation by dislocation generation or by cracking, which will reduce the electrical performance of the formed device. Cardwell and D'Evelyn [US 2021/0020798, US 2021/0167231] disclosed an approach to circumvent this problem, involving delivering electromagnetic radiation along long optical paths through an absorber layer to achieve near-100% optical absorption even when a relatively thin absorber layer containing power photodiode structure is provided. Additional benefits of their approach include excellent heat dissipation, zero or very low grid shadow losses, and long effective minority carrier lifetimes. Here, the effective minority carrier lifetime includes photon recycling, defined as reabsorption of photons emitted by the absorber layer. The term “light” and “optical radiation” are often used herein interchangeably and are both intended to generally describe electromagnetic radiation at one or more wavelengths unless otherwise noted in the context of the discussion.

Many of the embodiments disclosed by Cardwell and D'Evelyn [US 2021/0020798, US 2021/0167231] utilize multiple optical paths through the device layers via an optical cavity, in order to obtain the desired power conversion efficiency (PCE). The present inventors have discovered that a subset of these structures, together with a number of additions, refinements, and/or improved structures, yield excellent PCE with only two passes through the device layers and provide surprising benefits in the performance of the devices at elevated temperature. In particular, the inventive structures enable power photodiodes in which the temperature coefficients of the fill factor (FF), external quantum efficiency (EQE), and power conversion efficiency (PCE) are all positive. The inventors are not aware of any previously-disclosed power photodiode structures or devices that have all these properties.

In particular, the use of multiple-quantum-well (MQW) absorber layers, also known as active regions or active layers, with (Al)InGaN wells and (Al)(In)GaN barriers between wells and surrounding the absorber region in nitride photodiodes can delay the on-set of strain-induced defect generation, and thereby enable greater total thickness of absorbing (Al)InGaN in the absorber region, or higher indium (In) fraction in the absorbing layers for a given absorber thickness. However, the presence of barrier layers can impede the collection of photogenerated carriers from the absorber region, leading to degradation of the fill factor, especially at elevated input optical power densities. This carrier collection problem can be exacerbated by built-in polarization fields generated in the nitrides. It has been found that tuning the photodiode epitaxial structure for a given photodiode operating temperature, input wavelength, and input power density/distribution in such a way that the fill factor and the power conversion efficiency have positive temperature coefficients near the photodiode operating temperature can maximize the photodiode power conversion efficiency, even with just a two-pass device architecture. The tuning of the photodiode epitaxial structure has included optimizing the thickness and composition of well and barrier layers, the thickness and composition of a superlattice layer, doping levels in and thicknesses of dopant, cladding, and contact layers, and the like.

A power nitride photodiode that efficiently converts optical energy to electrical energy and can operate at elevated temperatures is suitable for applications requiring high temperature operation where more traditional, lower bandgap photodiodes or photovoltaics are more substantially degraded by elevated temperatures. Additionally, the capability of nitride photodiodes to maintain high efficiency at elevated temperatures and power levels can enable packaged photodiode modules with higher power densities without requiring active cooling. Power nitride photodiodes can be used in power-over-fiber or power-over-air systems. Such systems may have applications in automotive, aviation, lighting, etc.

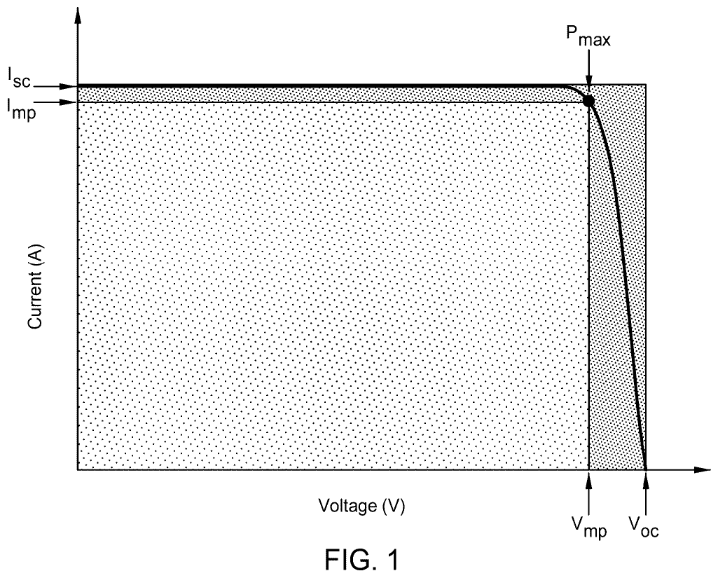

The power conversion efficiency (PCE) η of a power photodiode may be written as η=Vₘₚ×Iₘₚ/Pᵢₙ, where Pᵢₙ is the input radiative power, Vₘₚ is the voltage at the maximum obtainable power and Iₘₚ is the current at the maximum obtainable power. Another way of expressing the PCE is η=V_{oc}×I_{sc}× FF/Pᵢₙ, as illustrated schematically in FIG. 1, where V_{oc} is the open-circuit voltage, I_{sc} is the short-circuit current, and FF is the fill factor. Fill factor (FF) can be defined by the equation (Iₘₚ×Vₘₚ)/(I_{sc}×V_{oc}), which is illustrated as the ratio of the areas of the smaller and larger dotted rectangle areas in FIG. 1. Still another way of expressing the PCE of a semiconductor photodiode is η=(eV_{oc}/E_{g})×OA×IQE×FF×E_{g}/(hν), where e is the charge of an electron, E_{g} is the band gap of the semiconductor, OA is the optical absorption (or fraction of incident photons absorbed in the absorber layer), IQE is the internal quantum efficiency (fraction of absorbed photons producing an electron-hole pair that is collected), h is Planck's constant, and ν is the photon frequency. In preferred embodiments, the FF is greater than 70%, greater than 80%, greater than 90%, or greater than 95%. A high fill factor implies the capability of the device or device structure to efficiently collect photogenerated electrons and holes under forward bias, unlike the operation mode of photodetectors, for example. In general, achievement of a high FF requires careful attention to and optimization of band offsets and electric fields within the device structure, including doping levels, over a range of bias conditions. Further details of considerations for achieving high FF in the nitrides, for example, optimization of the cladding layers, are described by Cardwell and D'Evelyn [US 2021/0020798, US 2021/0167231], which are hereby incorporated by reference in their entirety.

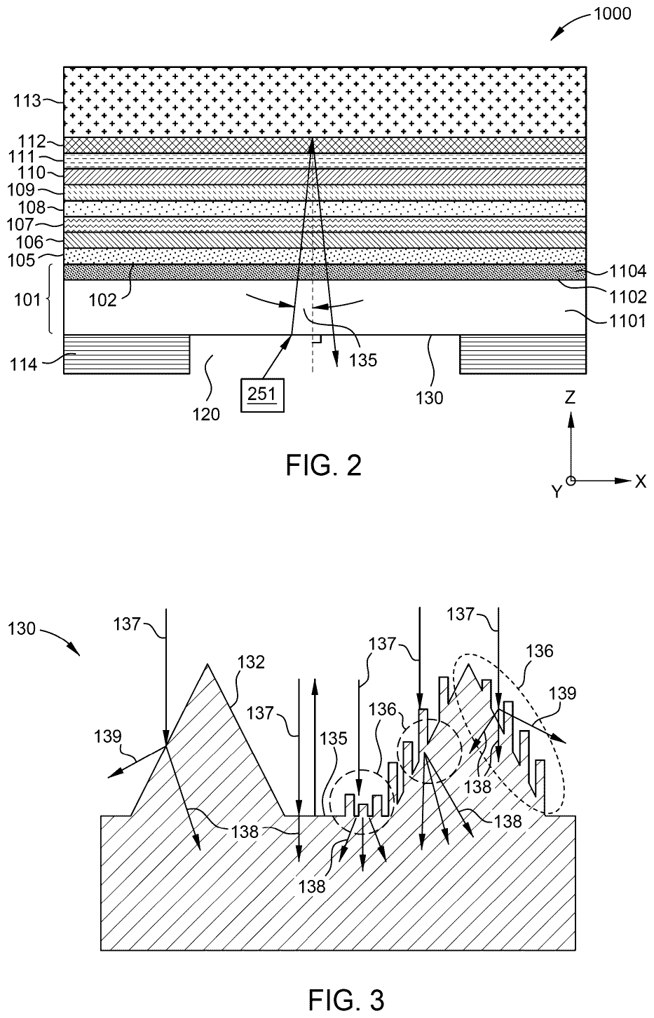

Relative to prior art photodiodes designed for much lower photon fluxes, mostly fabricated using GaN-on-sapphire structures, the inventive photodiodes, including GaN-on-GaN structures, feature high conversion efficiency due to careful optimization of the composition and doping of the semiconductor layers and to large area p-side electrical contacts with high reflectivity for use with a two-reflection excitation architecture and with very low contact resistance to minimize lateral ohmic losses at high current densities. In certain embodiments, the current photodiode structures are designed for applications where illumination is provided by a single laser or multiple lasers and enters the structure though an edge or through an aperture. In certain embodiments, the laser light is coupled into an aperture formed in the photodiode structure using optical fibers, lenses, or waveguides. In certain embodiments, the inventive photodiode structures further incorporate a much lower dislocation density, with longer minority carrier diffusion lengths to enable higher currents plus longer minority carrier lifetimes to achieve higher open circuit voltages and fill factors. In addition, the inventive devices may include electrically conductive substrates, enabling vertical transport in vertically oriented power devices for a simpler design and reduced series resistance, and transparent substrates with a very similar refractive index of that of the absorber layers, minimizing optical losses. For example, as illustrated in FIG. 2, the vertical current transport is oriented in the Z-direction from the substrate 101.

FIG. 2 depicts a simplified diagram of group III-metal nitride based photodiode structures 1000 (or devices 1000). Referring to FIG. 2, a substrate 101 is provided. In certain embodiments, substrate 101 comprises single-crystalline group-III metal nitride, gallium-containing nitride, or gallium nitride. Substrate 101 may be grown by HVPE, ammonothermally, or by a flux method. In certain embodiments, substrate 101 is a template, where a single-crystalline group-III metal nitride layer 1104 has been deposited or grown on a template substrate 1101 that consists of or includes a material such as sapphire (Al₂O₃), silicon carbide (SiC), or silicon. One or both large area surfaces of substrate 101 may be polished and/or chemical-mechanically polished. In certain embodiments, template substrate 1101 consists of or includes sapphire and has a large-area surface 1102 that has a crystallographic orientation within 5 degrees, within 2 degrees, within 1 degree, or within 0.5 degree of the (0001) crystal plane. Large-area surface 102 of substrate 101 may be characterized by a miscut in a <10-10> m-direction between about 0.2 degree and about 1 degree and by a miscut in a <11-20> a-direction that is less than about 0.2 degree. In certain embodiments, template substrate 1101 has a cubic structure and a large-area surface 1102 that has a crystallographic orientation within 5 degrees, within 2 degrees, within 1 degree, or within 0.5 degree of a {111} crystal plane. Other orientations may also be chosen.

Large-area surface 102 may have a maximum dimension between about 0.2 millimeter and about 600 millimeters and a minimum dimension between about 0.2 millimeter and about 600 millimeters and substrate 101 may have a thickness between about 10 micrometers and about 10 millimeters, or between about 100 micrometers and about 2 millimeters. In certain embodiments, substrate 101 is substantially circular, with one or more orientation flats or notches. In alternative embodiments, substrate 101 is substantially rectangular. In certain embodiments, large-area surface 102 has a maximum diametral dimension or rectangular-edge dimension of about 50 mm, 100 mm, 125 mm, 150 mm, 200 mm, 250 mm, 300 mm, or 450 mm. The variation in the crystallographic orientation of the large-area surface 102 may be less than about 5 degrees, less than about 2 degrees, less than about 1 degree, less than about 0.5 degrees, less than about 0.2 degrees, less than about 0.1 degrees, or less than about 0.05 degrees relative to the average crystallographic orientation of the large area surface.

Large-area surface 102 of substrate 101 may have a threading dislocation density less than about 10¹⁰ cm⁻², less than about 109 cm⁻², less than about 10⁸ cm⁻², less than about 107 cm⁻², less than about 10⁶ cm⁻², less than about 10⁵ cm⁻², less than about 104 cm⁻², less than about 103 cm⁻², or less than about 10² cm⁻². Large-area surface 102 of substrate 101 may have a stacking-fault concentration below about 104 cm⁻¹, below about 103 cm⁻¹, below about 10² cm⁻¹, below about 10 cm⁻¹ or below about 1 cm⁻¹. Large-area surface 102 of substrate 101 may have a symmetric x-ray rocking curve full width at half maximum (FWHM) less than about 500 arcsec, less than about 300 arcsec, less than about 200 arcsec, less than about 100 arcsec, less than about 50 arcsec, less than about 35 arcsec, less than about 25 arcsec, or less than about 15 arcsec. Large-area surface 102 of substrate 101 may have a crystallographic radius of curvature greater than 0.1 meter, greater than 1 meter, greater than 10 meters, greater than 100 meters, or greater than 1000 meters, in at least one or at least two independent or orthogonal directions. In a specific embodiment, large-area surface 102 of substrate 101 has a threading dislocation density less than about 10⁵ cm⁻², a stacking-fault concentration below about 10 cm⁻¹, and a symmetric x-ray rocking curve full width at half maximum (FWHM) less than about 50 arcsec. The reduced dislocation density in the substrate 101, relative to most prior art photodiodes, is expected to result in a reduced dislocation density in the semiconductor layers of the photodiode and to a higher open-circuit voltage V_{oc} and a higher efficiency at high current densities.

Substrate 101 may have a thickness between about 10 microns and about 100 millimeters, or between about 0.1 millimeter and about 10 millimeters. Substrate 101 may have a dimension, including a diameter, of at least about 5 millimeters, at least about 10 millimeters, at least about 25 millimeters, at least about 50 millimeters, at least about 75 millimeters, at least about 100 millimeters, at least about 150 millimeters, at least about 200 millimeters, at least about 300 millimeters, at least about 400 millimeters, or at least about 600 millimeters. In a specific embodiment, substrate 101 has a thickness between about 250 micrometers and about 600 micrometers, a maximum lateral dimension or diameter between about 15 millimeters and about 160 millimeters, and includes regions where the concentration of threading dislocations is less than about 104 cm⁻².

In certain embodiments, substrate 101 consists of or includes a single-crystalline group-III metal nitride layer 1104 bonded to or formed on a surface of a template substrate 1101. The single-crystalline group-III metal nitride layer 1104 may include gallium. The single-crystalline group III metal nitride layer 1104 may be deposited by HVPE, by metalorganic chemical vapor deposition (MOCVD), molecular beam epitaxy (MBE), or the like. The single-crystalline group-III metal nitride layer 1104 may have a thickness between about 1 micrometer and about 100 micrometers, between about 2 micrometers and about 25 micrometers, or between about 3 micrometers and about 15 micrometers. In certain embodiments, the single-crystalline group-III metal nitride layer 1104 has a wurtzite crystal structure and a crystallographic orientation within 5 degrees, within 2 degrees, within 1 degree, or within 0.5 degree of (0001)+c-plane. In certain embodiments, a nucleation layer (not shown) is present at the interface between the template substrate 1101 and the single-crystalline group-III metal nitride layer 1104. In certain embodiments, the nucleation layer consists of or includes one or more of aluminum nitride, gallium nitride, and zinc oxide. In certain embodiments, the nucleation layer is deposited on the template substrate 1101 by at least one of low-temperature MOCVD, sputtering, and electron-beam evaporation. In certain embodiments, the nucleation layer has a thickness between about 1 nanometer and about 200 nanometers or between about 10 nanometers and about 50 nanometers. In certain embodiments, the substrate further includes one or more strain-management layers, for example, an AlGaN layer or a strained-layer superlattice.

In certain embodiments, one or more n-type layers 105, comprising AlᵤInᵥGa₁₋ᵤ₋ᵥN layers, where 0≤u, v, u+v≤1, or, in a specific embodiment, GaN, is deposited on the substrate. The carrier concentration in n-type layer 105 may lie in the range between about 10¹⁶ cm⁻³ and 10²⁰ cm⁻³. In certain embodiments, silicon, germanium, or oxygen is the n-type dopant in n-type layer 105. In certain embodiments, the n-type carrier concentration in the n-type layer 105 lies in the range between 1×10¹⁸ cm⁻³ and 8×10¹⁸ cm⁻³. A high doping level may be particularly desirable if substrate 101 has a (0001)+c-plane orientation, as piezoelectric fields may more effectively be screened for efficient carrier collection. A high doping level may also be desirable if template substrate 1101 is electrically insulating or highly resistive. The deposition may be performed using metalorganic chemical vapor deposition (MOCVD) or molecular beam epitaxy (MBE). In certain embodiments, n-type layer 105 has a thickness between about 0.2 micrometer and about 5 micrometers, or between about 0.5 micrometer and about 1.5 micrometers.

In certain embodiments, a strained-layer superlattice (SLS) 106 is deposited on or overlying n-type layer 105. In certain embodiments, the SLS includes or consists of alternating layers of AlInGaN, where the alternating layers have a difference in In content of between about 0.5 atomic % and about 4 atomic %, where the atomic % is expressed as a metal fraction (i.e., as a percentage of the total of In, Ga, and Al). In a specific embodiment, the SLS includes or consists of alternating layers of GaN and InGaN, with the InGaN including an In content between about 0.5 atomic % and about 4 atomic % or between about 1 atomic % and about 3 atomic %, the layer thickness is between about 0.5 nanometer and about 3 nanometers or between about 1 nanometer and about 2 nanometers and a total of between about 25 and 80 GaN/InGaN layers are included. The layers in the SLS may be doped n-type, for example, using Si, Ge, and/or O, and may include a dopant level between about 1×10¹⁸ cm⁻³ and about 5×10¹⁹ cm⁻³ or between about 2×10¹⁸ cm⁻³ and about 4×10¹⁸ cm⁻³.

In certain embodiments, a lower cladding layer 107, also referred to herein as a lower barrier layer, may be deposited on or overlying strained-layer superlattice 106. Lower cladding layer 107 may include or consist of InGaN, with 0-4 atomic % of In, and may have a doping level between about 1×10¹⁹ cm⁻³ and about 5×10¹⁹ cm⁻³. In one example, the lower cladding layer 107 includes up to about 4 atomic % of indium (In), such as between 0.1 atomic % and 4 atomic %. As noted by Cardwell and D'Evelyn, a high doping level and/or the presence of In can improve carrier transport via favorable band lineups in +c-plane-oriented device structures. A high doping level may be particularly desirable if substrate 101 has a (0001)+c-plane orientation, as piezoelectric fields may be more effectively screened for efficient carrier collection. Lower cladding layer 107 may have a thickness between about 6 nanometers and about 14 nanometers.

An absorber layer 108, also referred to herein as an active layer, may be deposited on or overlying lower cladding layer 107. Absorber layer 108 may include or consist of a multiple quantum well (MQW), including alternating layers of Al_{w}InₓGa_{1-w-x}N well layers and Al_{y}In_{z}Ga_{1-y-z}N barrier layers, respectively, where 0≤w, x, y, z, w+x, y+z≤1, where w<u, y and/or x>v, z so that the bandgap of the well layer(s) is less than that of cladding layer 107, of strained-layer superlattice 106, and of n-type layer 105. The absorber layer 108 may include between 25 and 100, between 30 and 75, or between 35 and 50 quantum wells (not shown). The quantum wells may comprise InGaN well layers and GaN barrier layers. The well layers may each have a thickness between about 2 nanometers and about 5 nanometers, or between about 2.5 nanometers and about 4 nanometers. The barrier layers may each have a thickness between about 0.5 nanometer and about 2.5 nanometers, or between about 1 nanometer and about 2 nanometers. In certain embodiments, the absorber layer 108 is deposited by MOCVD, at a substrate temperature between about 700 and about 950 degrees Celsius.

In certain embodiments, the absorber layer 108 is unintentionally doped. In certain embodiments, the absorber layer 108 is n-type doped, using oxygen, silicon, or germanium, as a dopant, with a dopant concentration between about 5×10¹⁵ cm⁻³ and about 5×10¹⁹ cm⁻³, or between about 5×10¹⁶ cm⁻³ and about 5×10¹⁸ cm⁻³. In certain embodiments, the absorber layer 108 is p-type doped, using Mg as a dopant, with a dopant concentration between about 5×10¹⁵ cm⁻³ and about 5×10¹⁹ cm⁻³, or between about 5×10¹⁶ cm⁻³ and about 5×10¹⁸ cm⁻³. In some embodiments, the absorber layer 108 has a bandgap wavelength that is between about 360 and about 550 nanometers, such as a bandgap wavelength that is between about 400 nanometers and about 500 nanometers.

The composition and structure of the absorber layer 108 are chosen to provide light absorption at preselected wavelengths, for example, near 405 nanometers or near 450 nanometers. In certain embodiments, the wavelength for optimum absorption is selected to lie between about 360 nanometers and about 500 nanometers. The absorber layer 108 may be characterized by photoluminescence spectroscopy. In certain embodiments, the composition of the absorber layer 108 is chosen such that the photoluminescence spectrum has a peak that is longer in wavelength than the desired absorption wavelength of the photodiode structure 1000 by between 5 nanometers and 50 nanometers or by between 10 nanometers and 25 nanometers. In certain embodiments, the well layers contain In at between about 10 atomic % and about 14 atomic %. In certain embodiments, the quality and layer thicknesses within the absorber layer 108 are characterized by x-ray diffraction.

In certain embodiments, the absorber layer 108 is terminated by an upper barrier layer 109, which may also be referred to herein as a first upper barrier layer. Upper barrier layer 109 may consist of GaN, or InGaN, with 0-4 atomic % of indium (In). In one example, the upper barrier layer 109 includes up to about 4 atomic % of indium (In), such as between 0.1 atomic % and 4 atomic %. Upper barrier layer 109 may have a thickness between about 4 nanometers and about 10 nanometers. In certain embodiments, upper barrier layer 109 is unintentionally doped. In certain embodiments, upper barrier layer 109 has a graded composition, with the In concentration varying between a first level and a second level.

In certain embodiments, an upper cladding layer 110, which may also be referred to herein as a second upper barrier layer, is deposited on or overlying upper barrier layer 109. Upper cladding layer 110 may include or consist of heavily-Mg-doped GaN and may have a thickness between about 10 nanometers and about 30 nanometers or between about 16 nanometers and about 24 nanometers. Upper cladding layer 110 may have a Mg concentration between about 8×10¹⁹ cm⁻³ and about 6×10²⁰ cm⁻³ or between about 1.5×10²⁰ cm⁻³ and about 4×10²⁰ cm⁻³.

Next, a p-type layer 111, formed of Al_{q}InᵣGa_{1-q-r}N, where 0≤q, r, q+r≤1, or of GaN, is deposited on or overlying upper cladding layer 110. The p-type layer 111 may be doped with Mg, to a level between about 10¹⁸ cm⁻³ and 10²¹ cm⁻³, or between about 10¹⁹ cm⁻³ and about 8×10¹⁹ cm⁻³, and may have a thickness between about 5 nanometers and about 100 nanometers or between about 25 nanometers and about 75 nanometers.

A p-contact layer 112 may then be deposited on or overlying p-type layer 111. The p-contact layer 111 may be doped with Mg, to a level between about 10¹⁹ cm⁻³ and 10²² cm⁻³, or between about 10²⁰ cm⁻³ and about 6×10²⁰ cm⁻³, and may have a thickness between about 2 nanometers and about 50 nanometers, between about 10 nanometers and about 25 nanometers.

The semiconductor layers, which include the n-type layer 105, the strained-layer superlattice 106, the lower cladding layer 107, the absorber layer 108, the upper barrier layer 109, the upper cladding layer 110, the p-type layer 111, and the p-contact layer 112, are epitaxial and have the same crystallographic orientation, to within about two degrees, within about one degree, within about 0.5 degree, or within about 0.2 degree, as the crystallographic orientation of large-area surface 102 of substrate 101, have a very high crystalline quality, comprise nitrogen, and may have a surface dislocation density below 109 cm⁻². The semiconductor layers may have a surface dislocation density below 10¹⁰ cm⁻², below 109 cm⁻², below 10⁸ cm⁻², below 107 cm⁻² below 10⁶ cm⁻², below 10⁵ cm⁻², below 104 cm⁻², below 103 cm⁻², or below 10² cm⁻². The semiconductor layers may have a dislocation density that is within a factor of five, a factor of two, or a factor of 1.2 of the dislocation density of large-area surface 102.

In a specific embodiment, the semiconductor layers have an orientation within five degrees of (0001) c-plane and the FWHM of the 0002 x-ray rocking curve of the top surface is below 300 arc sec, below 100 arc sec, or below 50 arc sec.

In order to maximize the efficiency of a packaged photodiode, it may be important to maximize the reflectivity of the top side of the photodiode structure 1000 and also to minimize the electrical resistance of the contacts in the photodiode structure. Referring again to FIG. 2, a p-side reflective electrical contact 113 may be deposited on or overlying the p-type layer 111, or on the p-contact layer 112, if the latter is present. In a preferred embodiment, the average reflectivity of the reflective p-side electrical contact is greater than 70%, greater than 80%, greater than 85%, greater than 90%, greater than 95%, greater than 97%, or greater than 98% at a specific angle or range of angles at which light is incident during operation, for example angles 135 between 0 and 20 degrees from normal (i.e., the direction perpendicular to large area surface 102 in FIG. 2). From Snell's law, the incident angle 135 within the semiconductor layers will in general be less than the incident angle of light onto planar portions of backside surface 130. In general, the term “average reflectivity” as used herein is intended to broadly describe a reflectance value that is calculated by averaging at least two reflectance measurement data points on a surface at a specific wavelength between 360 nanometers and 500 nanometers and at one or more angles with respect to the surface of the layer that are representative of the range of incident angles during device operation. In some embodiments, light is coupled into the device through an aperture 120 and the angle of incidence on the p-side reflective electrical contact 113 internally is between about 0 and about 60 degrees, between about 0.2 and about 40 degrees, or between about 0.3 and about 20 degrees, as measured from the plane of the semiconductor layers. The contact resistance of the p-side reflective electrical contact is less than 3×10⁻³ Ωcm², less than 1×10⁻³ Ωcm², less than 5×10⁻⁴ Ωcm², less than 2×10⁻⁴ Ωcm², less than 10⁻⁴ Ωcm², less than 5×10⁻⁵ Ωcm², less than 2×10⁻⁵ Ωcm², or less than 10⁻⁵ Ωcm². In preferred embodiments, the contact resistance is less than 1×10⁻⁴ Ωcm². The p-side reflective electrical contact may include at least one of silver, gold, aluminum, nickel, platinum, rhodium, palladium, titanium, chromium, germanium, ruthenium, magnesium, scandium, or the like. In some embodiments, the p-side reflective electrical contact 113 may include or consist of at least two layers, with a first layer providing a good electrical contact and comprising platinum, nickel, aluminum, or titanium and having a thickness between 0.1 and 5 nanometers, and a second layer providing superior optical reflectivity and comprising silver, gold, or nickel and having a thickness between 0.4 nanometer and 1 micrometer. In certain embodiments, the p-side reflective electrical contact 113 may include or consist of at least three layers, at least four layers, or at least five layers. In certain embodiments, the p-side reflective electrical contact 113 comprises three layers, with the first layer comprising silver, with a thickness between about 1 nanometer and about 200 nanometers, a second layer comprising a moderately oxophilic metal, with a thickness between about 0.5 nanometer and about 2 nanometers, and a third layer comprising silver, with a thickness between about 50 nanometers and about 200 nanometers. In certain embodiments, the moderately oxophilic metal includes or consists of nickel. In certain embodiments, the moderately oxophilic metal includes or consists of or includes one or more of copper, cobalt, iron, and manganese. In certain embodiments, the reflective p-side electrical contact is annealed after deposition to improve its reflectivity and/or to reduce its contact resistance. In certain embodiments, the annealing is performed in a rapid thermal anneal (RTA) furnace, to a temperature between about 300 degrees Celsius and about 1000 degrees Celsius. In certain embodiments the p-side reflective electrical contact 113 is annealed to a temperature between about 500 and about 900 degrees Celsius under a controlled atmosphere containing oxygen at a partial pressure between about 0.1 Torr and about 200 Torr, so as to cause interdiffusion between the moderately oxophilic metal and silver and introduction of a controlled concentration of oxygen atoms into the p-side reflective electrical contact layer. In preferred embodiments, the partial pressure of oxygen is reduced below about 10⁻⁴ Torr before cooling the p-side reflective electrical contact below a temperature of about 250 degrees Celsius, so as to avoid formation of excess silver oxide. In certain embodiments, the p-side reflective electrical contact 113 includes oxygen with a maximum local concentration between about 1×10²⁰ cm⁻³ and about 7×10²⁰ cm⁻³. In certain embodiments, the p-side electrical contact includes or consists of at least four layers, where the first layer includes or consists of at least one of platinum or nickel and has a thickness between about 0.25 nanometer and about 3 nanometers, or between about 0.5 nanometer and about 2 nanometers, the second layer includes silver and has a thickness between about 1 nanometer and about 200 nanometers, the third layer includes a moderately oxophilic metal and has a thickness between about 0.5 nanometer and about 2 nanometers, and the fourth layer includes at least one of silver or gold and has a thickness between about 50 nanometers and about 500 nanometers. The p-side reflective electrical contact may be deposited by thermal evaporation, electron beam evaporation, sputtering, or another suitable technique. In a preferred embodiment, the p-side reflective electrical contact serves as the p-side electrode for the power photodiode. In certain embodiments, the p-side reflective electrical contact is planar and parallel to the semiconductor layers, which may be useful for maximizing its reflectivity. In alternative embodiments, the p-side reflective electrical contact is patterned or textured.

Referring again to FIG. 2, in certain embodiments, an n-side reflective electrical contact 114, with an average reflectivity greater than about 70%, is deposited on or overlying the back side of substrate 101. In a preferred embodiment, the average reflectivity of the reflective n-side electrical contact is greater than 80%, greater than 85%, greater than 90%, greater than 95%, greater than 97%, or greater than 98% at a specific angle or range of angles at which light is incident during operation. The contact resistance of the reflective n-side electrical contact is less than 1×10⁻³ Ωcm², less than 5×10⁻⁴ Ωcm², less than 2×10⁻⁴ Ωcm², less than 10⁻⁴ Ωcm², less than 5×10⁻⁵ Ωcm², less than 2×10⁻⁵ Ωcm², or less than 10⁻⁵ Ωcm². In preferred embodiments, the contact resistance is less than 5×10⁻⁵ Ωcm². The reflective n-side electrical contact may comprise at least one of silver, gold, aluminum, nickel, platinum, rhodium, palladium, titanium, chromium, or the like. In some embodiments, the reflective n-side electrical contact may include or consist of at least two layers, with a first layer providing a good electrical contact and comprising aluminum or titanium and having a thickness between 0.1 and 5 nanometers, and a second layer providing superior optical reflectivity and comprising aluminum, nickel, platinum, gold, or silver and having a thickness between 10 nanometers and 10 micrometers. In certain embodiments, the n-side reflective electrical contact may include or consist of at least three layers, at least four layers, or at least five layers, so as to co-optimize the reflectivity (maximized), the contract resistance (minimized), and the robustness (maximized). The reflective n-side electrical contact may be deposited by thermal evaporation, electron beam evaporation, sputtering, or another suitable technique. In certain embodiments, the n-side reflective electrical contact serves as the n-side electrode for the power photodiode. In certain embodiments, the n-side reflective electrical contact is planar and is aligned parallel to the semiconductor layers, which may be useful for maximizing its reflectivity. In alternative embodiments, the n-side reflective electrical contact is patterned or textured, which may be useful for admission or extraction of light, for example, within an aperture.

In certain embodiments, particularly embodiments where the n-side reflective electrical contact includes aluminum, in order to reduce the contact resistance of the n-side reflective electrical contact, the back side of substrate 101 is processed by reactive ion etching (RIE) using a chlorine-containing gas or plasma. In one specific embodiment, the chlorine-containing gas or plasma includes SiCl₄. In certain embodiments, in order to reduce the contact resistance of the n-side reflective electrical contact, further cleaning steps are performed. In certain embodiments, the further cleaning steps include or consist of one or more of treatment by a mineral acid, such as hydrochloric acid, nitric acid, or aqua regia, a buffered oxide etch, by dry etching, or by treatment with a plasma, such as an argon plasma.

In certain embodiments, for example, where substrate 101 is a template that includes an insulating template substrate 1101, an n-side electrical contact is deposited instead on a portion of at least one of n-type layer 105, strained-layer superlattice (SLS) 106, or lower cladding layer 107, for example, at the bottom of a trench (not shown) that is formed through absorber layer 108.

The photodiode structures 1000 described in the present disclosure are intended for use in a photodiode die that is disposed within a packaged photodiode assembly, and, typically, includes a single-reflection geometry. The photodiode die, or simply “die”, typically includes a portion of a substrate that is formed by a singulation, cleaving or other similar process and includes the various photodiode structure 1000 elements described herein. In some embodiments, a photodiode die includes a photodiode structure having aperture 120 (FIG. 2) that is placed within the packaged photodiode assembly and is configured to receive one or more wavelengths of electromagnetic radiation, which is also referred to herein as light, from an illumination source 251. The illumination source 251 may include a laser, a fiber optic cable coupled to a laser, or other useful radiation source. Referring again to FIG. 2, in certain embodiments, the backside surface 130 of substrate 101 is smooth. In certain embodiments, an anti-reflection coating is deposited on backside surface 130. The anti-reflection coating may include a material selected from a group including MgF₂, SiO₂, Al₂O₃, HfO₂, LaTiO₃, Si₃N₄ or TiO₂ and may be deposited by electron beam deposition, ion-beam deposition, sputtering, or other suitable deposition techniques. One or more dies may be prepared from the photodiode structures described above, for example, by dicing, singulation, cleaving, or the like. The dies may have a square, rectangular, triangular, or other shape. The die may be bounded by edge structures, such as one or more of a passivating layer and reflective coatings.

In certain embodiments, at least a portion of backside surface 130 of the substrate 101 is roughened, to facilitate light entry into the device structure and to help trap the light within it, as shown schematically in FIG. 3. In certain embodiments, an anti-reflection coating is applied to the roughened backside surface. In certain embodiments, backside roughening is provided by formation of pyramid structures on backside surface 130. In one specific embodiment, backside surface 130 consists essentially of GaN having a crystallographic orientation within about 5 degrees of (000-1), and hexagonal-shaped pyramid structures 132 are formed by exposure to a solution that includes at least one of potassium hydroxide (KOH) and sodium hydroxide (NaOH), at a concentration between about 0.1 molar and about 12 molar, at a temperature between about 0 degrees Celsius and about 90 degrees Celsius, for a time between about 30 seconds and about five hours. In certain embodiments, each of the hexagonal-shaped pyramid structures 132 has a peak-to-peak height ranging from about 0.3 micrometer to about 30 micrometers, and a lateral dimension or diameter of a base region ranging from about 0.3 micrometer to 30 micrometers. In certain embodiments, each of a plurality of hexagonal-shaped pyramid structures 132 extends from a crystalline structure of the gallium and nitrogen containing substrate member, and has an irregularity in size ranging from 0% to 50%, but there can be others. In certain embodiments, surface 130 has an interior region 135 (typically planar in shape) disposed between a pair of the plurality of hexagonal shaped pyramid structures 132. In certain embodiments, the pyramidal structures are present in 50%-100% of the surface area of the exposed portion of the backside surface.

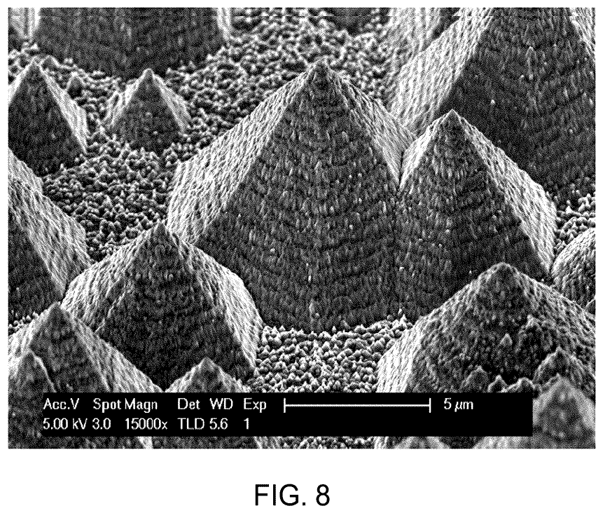

Referring again to FIG. 3, in certain embodiments nanodot or nanopillar structures are fabricated on surface 130, for example, above pyramidal structures 132, to further improve light admission and coupling to the active layer for absorption. In certain embodiments, surface 130 has a plurality of nanodot structures 136 spatially disposed overlying the interior region 135 and overlying a surface region of each of the plurality of hexagonal-shaped pyramid structures 132 and configured to direct incident electromagnetic radiation 137 having a wavelength ranging from 360 to 500 nanometers to the absorber layer 108 to increase an absorption of the radiation into the absorber layer, and thereby coupling additional radiation into the absorber layer. The nanodot structures 136 generally include a plurality of facets that are formed in the surface of the pyramid structures 132. In one example, as shown in FIG. 8, the faceted structures of the nanodot structures 136 are between about 0.05 and about 0.6 micrometers (μm) in size. As illustrated in FIG. 3, the incident electromagnetic radiation 137 is provided to the surface 130, and the nanodot structures 136 are configured to increase the amount of transmitted radiation 138 relative to the amount of reflected radiation 139. The nanodot structures are thus configured to increase an absorption of the radiation within the absorber layer 108, and thereby coupling additional radiation into the absorber layer during operation. The nanodot structures can include gallium nitride.

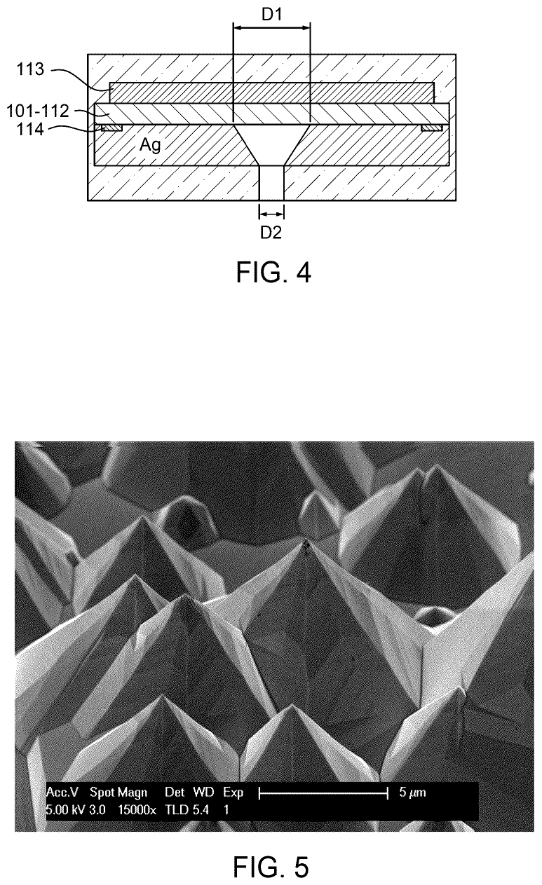

In certain embodiments, a chip or die that includes a photodiode structure such as that described above is incorporated into an optical cavity, many examples of which are described by Cardwell and D'Evelyn. In one specific embodiment, the optical cavity may include a tapered hole within a silver foil or plate, as shown schematically in FIG. 4. Light may be incident through a cavity aperture having diameter D2 onto backside surface 130, with die entrance aperture D1 (which may correspond to aperture 120 in FIG. 2). Any reflected light, particularly if it is reflected at an oblique angle (as in FIG. 3), may be reflected by conical sides of the cavity back toward die entrance aperture 120.

In the inventive structures described herein, the absorber layer 108 includes a large number of relatively thin well and barrier layers, with the large number enabling quite robust external quantum efficiencies, even with only two optical passes through the absorber layer, and the thinness of the MQW layers (specifically, the barrier layers) serves a dual purpose of strain management and maintenance of high carrier collection efficiency and improved fill factor. This combination, together with the addition of an upper barrier layer, which the inventors have found improves device performance, is found to give rise to the unanticipated, and surprising, result that each of the fill factor, the external quantum efficiency, and the power conversion efficiency increase over the temperature range between 25 degrees Celsius and 80 degrees Celsius. In certain embodiments, the fill factor increases by at least 2%, at least 3%, at least 4%, at least 5%, or at least 6% as the temperature of the semiconductor layers within the photodiode device area is increased from 25 degrees Celsius to 80 degrees Celsius. In certain embodiments, the external quantum efficiency increases by at least 1%, at least 2%, or at least 3% as the temperature of the semiconductor layers within the photodiode device area is increased from 25 degrees Celsius to 80 degrees Celsius. In certain embodiments, the power conversion efficiency increases by at least 2%, at least 3%, at least 4%, at least 5%, or at least 6% as the temperature of the semiconductor layers within the photodiode device area is increased from 25 degrees Celsius to 80 degrees Celsius. In certain embodiments, each of the fill factor, the external quantum efficiency, and the power conversion efficiency increase monotonically over the temperature range between 25 degrees Celsius and 70 degrees Celsius. Without wishing to be bound by theory, the inventors believe that this phenomenon is due to phonon-assisted tunneling.

In other words, phonons within the semiconductor layers are able to assist carriers in surmounting the barrier heights created by the various barrier layers, including barrier layers within the multiple quantum well within the absorber layer 108 and the upper barrier layer 109. The inventors further believe that the SLS, positioned below the lower cladding layer, helps reduce the concentration of point defects, such as Shockley-Read-Hall defects, that can lead to non-radiative recombination, within the absorber layer and within the cladding layers, thereby increasing the EQE.

### EXAMPLES

Embodiments provided by the present disclosure are further illustrated by reference to the following comparative examples and exemplary process examples. It will be apparent to those skilled in the art that many modifications, both to materials, and methods, may be practiced without departing from the scope of the disclosure.

### Example 1

An epitaxial structure similar to FIG. 2 is grown on a bulk GaN substrate having a crystallographic surface orientation miscut from (0001) by about 0.4 degrees toward a <10-10> m-direction. An n-type layer, with a silicon dopant concentration of approximately 3×10¹⁸ cm⁻³, is grown on the substrate by MOCVD to a thickness of approximately 1 micrometer, followed by a strained-layer superlattice, consisting of 50 alternating layers of In_{0.04}Ga_{0.96}N and GaN, each having a silicon dopant concentration of approximately 3×10¹⁸ cm⁻³ and a thickness of about 1.5 nanometers. Next, a lower cladding layer of In_{0.04}Ga_{0.96}N is deposited, with a thickness of approximately 10 nanometers and a silicon dopant concentration of approximately 3×10¹⁹ cm⁻³. Next, a multiple quantum well, consisting essentially of 40 pairs of an unintentionally-doped InGaN well layer, 3.5 nanometers thick, and an unintentionally-doped GaN barrier layer, 1.5 nanometers thick, is grown, followed by an upper cladding layer of unintentionally-doped GaN, 8 nanometers thick. Next, an upper cladding layer of In_{0.04}Ga_{0.96}N is deposited, having a magnesium dopant concentration of approximately 2×10²⁰ cm⁻³, and a thickness of approximately 20 nanometers, followed by a p-type layer, consisting essentially of GaN with a magnesium dopant concentration of approximately 3×10¹⁹ cm⁻³, and a thickness of approximately 60 nanometers, followed in turn by a p-contact layer, consisting essentially of GaN with a magnesium dopant concentration of approximately 3×10²⁰ cm⁻³, and a thickness of approximately 15 nanometers. Next, after the substrate and semiconductor layers is removed from the MOCVD reactor and placed in an electron-beam deposition apparatus, a three-layer p-contact is deposited, including a 100 nanometer layer of silver, a 1 nanometer layer of nickel, and a 100 nanometer layer of silver.

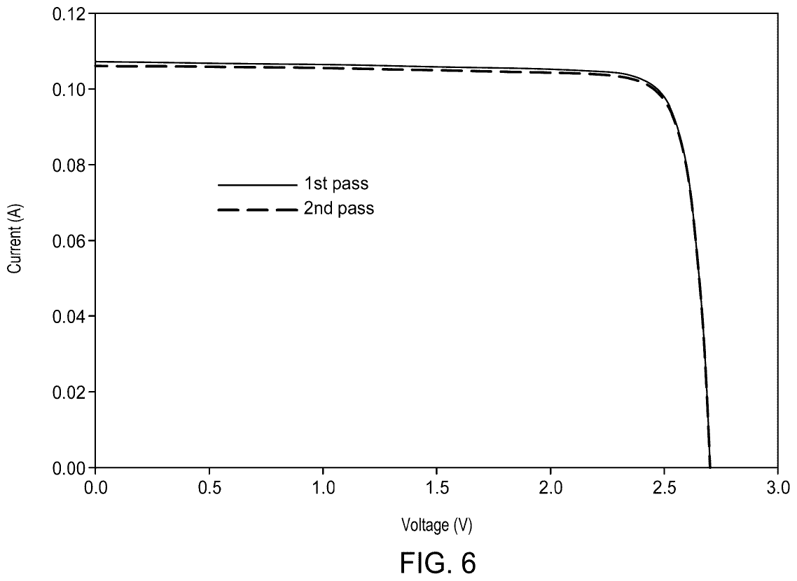

Hexagonal pyramidal structures are then formed on the backside of the substrate, by exposure to a 2.3 molar solution of KOH at a temperature of approximately 60 degrees Celsius for approximately one hour. The morphology of the hexagonal pyramidal structures is similar to that shown in FIG. 5. A reflective n-contact, including a 200 nanometer-thick Al layer, a 100 nanometer-thick Ti layer, a 100 nanometer-thick Ni layer, followed by a 200 nanometer-thick Au layer, are sequentially deposited on a portion of the roughened backside substrate surface by electron-beam evaporation, leaving another portion of the roughened backside substrate surface exposed. An anti-reflection coating, consisting essentially of SiO₂ and having a thickness of approximately 70 nanometers, is then deposited by an ion-beam deposition process on at least the exposed portion of the backside of the substrate. A simple optical cavity, including a silver (Ag) plate with a counter-sunk hole similar to that shown schematically in FIG. 4, is provided. In one configuration, as shown in FIG. 4, the inlet portion (i.e., light receiving portion) of the counter-sunk hole has a diameter D2 and the outlet end of the counter-sunk region of the counter-sunk hole has a diameter D1, where D1 is greater than D2. In a specific example, the values of D1 and D2 are 0.6 mm and 1.7 mm, respectively. One of the devices on the substrate then undergoes wafer-level current-voltage (I-V) measurements, both in the dark and under illumination by 406 nm laser light having a power level of 0.4 to 0.5 watt, as measured using a calibrated power meter. The room-temperature light-current-voltage (LIV) response is shown in FIG. 6. With the optical cavity present, the external quantum efficiency is measured as 82.9%, and the power conversion efficiency is measured as 62.3%. With the optical cavity removed, the external quantum efficiency is measured as 78.6%, and the power conversion efficiency is measured as 59.2%. The fill factor, in both cases, is approximately 85%. The similarity of the values with the optical cavity absent to those with the optical cavity present indicates that the large majority of power generation occurs from just two passes of light through the absorber layer, the first pass after admission through an aperture 120 formed between the reflective n-contacts in the backside surface 130 and the second pass after reflection from the p-side reflective electrical contact 113.

### Example 2

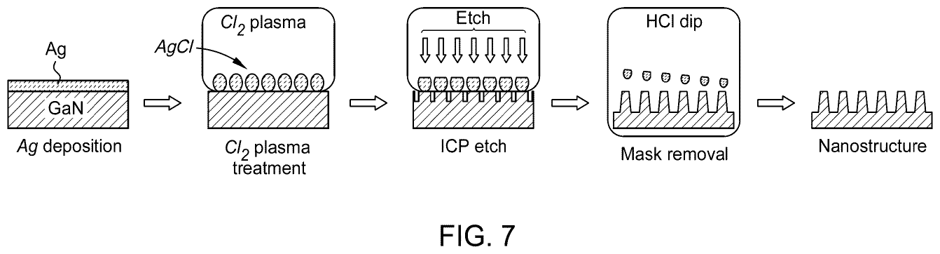

Hexagonal pyramidal structures similar to those shown in FIG. 5 are formed on the backside of a photodiode substrate by a similar process to that described in Example 1. A silver layer, approximately 100 nanometers thick, is then deposited on the hexagonal pyramidal structures by electron-beam evaporation. The silver layer is then exposed to an inductively-coupled plasma (ICP) containing Cl₂ to form a AgCl hard mask. The coated, hexagonal pyramidal structures undergo approximately 200 seconds of etching by the ICP plasma, and then the remaining AgCl residue is removed by dipping in aqueous hydrochloric acid. The process flow is shown schematically in FIG. 7. A plurality of nanodot structures 136, similar to those shown schematically in FIG. 3, is formed, as shown in FIG. 8.

### Example 3

A device structure similar to that described in Example 1 and shown in FIG. 2 is fabricated. A reflective Al n-type metallic contact, including two perimeter contact pads, is deposited on the backside of the substrate. An individual die, chip, or device is prepared by singulating the substrate, and a SiO₂ mesa edge passivation is deposited. The electroluminescence peak wavelength of the device occurs at 418 nanometers.

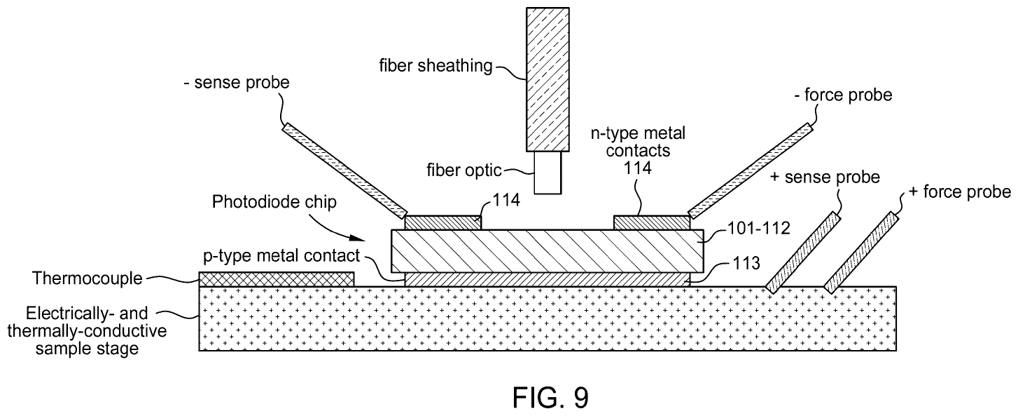

The electrical and photoelectrical characteristics of the device are measured using a setup similar to that shown schematically in FIG. 9. FIG. 9 is a schematic illustration of a fiber-illuminated current-voltage test setup used to measure illuminated current-voltage curves on nitride photodiode chips. The photodiode is seated on an electrically and thermally-conductive sample stage that provides a surface for a positive sense probe and a positive force probe. The two perimeter contact pads provide a surface for a corresponding negative sense probe and negative force probe.

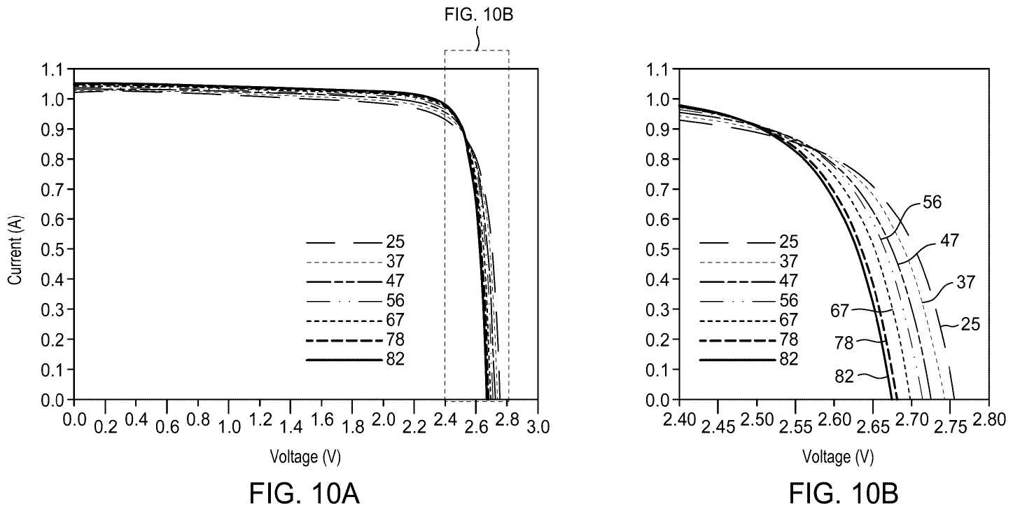

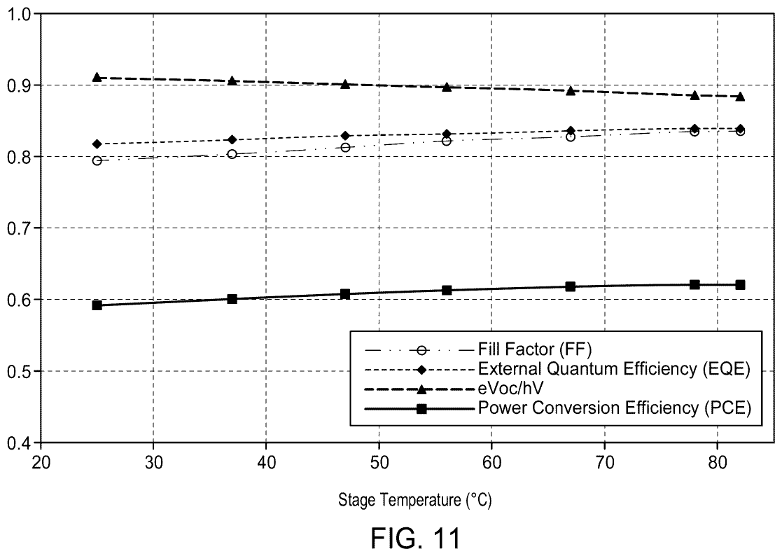

The die or chip described above undergoes fiber-illuminated current-voltage testing using a test configuration as shown in FIG. 9, using 410 nanometer wavelength laser light at a power level of 3.78 watts, as measured using a calibrated power meter. The stage is heated using thin-film resistive heaters. A thermocouple mounted on the sample stage measures the testing temperature of the photodiode chip. The dark and light I-V responses are measured at stage temperatures ranging from 25 degrees Celsius to 82 degrees Celsius The LIV response is shown in FIG. 10A, and a close-up view of a portion of the results shown in FIG. 10A is shown in FIG. 10B. The open-circuit voltage ratio (eV_{OC}/hν), fill factor (FF), external quantum efficiency (ECE), and power conversion efficiency (PCE) are evaluated from the LIV curves at each temperature. The results are shown in FIG. 11. The open-circuit voltage is seen to decrease with temperature, as expected from the known decrease in bandgap with temperature. However, for the first time, to the best of the inventor's knowledge for a semiconductor-based photodiode, the fill factor, external quantum efficiency, and power conversion efficiency all increase for stage temperatures between 25 degrees Celsius and 75 degrees Celsius. In particular, the PCE increases from 59% at 25° C. to 62% at 82° C., an increase of 4.9%, due to increases in both the fill factor (by 5.4%) and EQE (by 2.6%) with increasing temperature, which overcomes the expected decrease in eV_{oc}/hν (by 3.0%) with increasing temperature. Therefore, in applications where a photodiode device sees an increase in operating temperature above ambient temperature the device performance will be increased. Thus, in some applications the need to actively cool a photodiode device is lessened, or in some other configurations it may be desirable to actively heat the photodiode device to improve its performance.

While the foregoing is directed to embodiments of the present disclosure, other and further embodiments of the disclosure may be devised without departing from the basic scope thereof, and the scope thereof is determined by the claims that follow.

What is claimed is:

1. A photodiode device, comprising:
a die comprising at least one multiple quantum well layer disposed between an n-type layer and an upper barrier layer, with a p-type layer overlying the upper barrier layer, each of the at least one multiple quantum well layer, the n-type layer, the upper barrier layer, and p-type layer comprising AlₓIn_{y}Ga_{1-x-y}N, where 0≤x, y, x+y≤1 and having a dislocation density below about 10¹⁰ cm⁻²; wherein
the at least one multiple quantum well layer comprises at least 25 pairs of a well layer and a barrier layer, the well layers having a thickness, measured in a first direction, between about 2 nanometers and about 5 nanometers, and the barrier layers having a thickness, also measured in a first direction, between about 0.5 nanometer and about 2.5 nanometers;
the p-type layer has a thickness, measured in the first direction, between 1 nanometer and 1000 nanometers;
the upper barrier layer has a thickness between about 4 nanometers and about 10 nanometers and comprises up to about 4 atomic percent of indium (In), expressed on a metals basis;
each of the at least one multiple quantum well layer, the n-type layer, the upper barrier layer, and p-type layer have a crystallographic orientation within 5 degrees of c-plane and are parallel to a first plane that is oriented normal to the first direction;
the die is characterized by a fill factor (FF) that increases in value as a temperature of the die is increased from about 25 degrees Celsius to about 80 degrees Celsius, wherein the fill factor is measured using light having a wavelength between 360 nanometers and 500 nanometers.

2. The photodiode device of claim 1, wherein the fill factor is at least 70% at a temperature of about 25 degrees Celsius and increases by at least 2% as a temperature of the die is increased to about 80 degrees Celsius.

3. The photodiode device of claim 1, wherein the die is further characterized by an external quantum efficiency that increases in value as a temperature of the die is increased from about 25 degrees Celsius to about 80 degrees Celsius.

4. The photodiode device of claim 3, wherein the external quantum efficiency is at least 70% at a temperature of about 25 degrees Celsius and increases by at least 1% as a temperature of the die is increased to about 80 degrees Celsius.

5. The photodiode device of claim 1, wherein the die is further characterized by a power conversion efficiency that increases as a temperature of the die is increased from about 25 degrees Celsius to about 80 degrees Celsius.

6. The photodiode device of claim 5, wherein the power conversion efficiency is at least 50% at a temperature of about 25 degrees Celsius and increases by at least 2% as a temperature of the die is increased to about 80 degrees Celsius.

7. The photodiode device of claim 1, wherein the well layers have an In content between 10 atomic % and 14 atomic %.

8. The photodiode device of claim 1, wherein each of the at least one multiple quantum layer and the upper barrier layer are unintentionally doped.

9. The photodiode device of claim 1, wherein the n-type layer has a thickness, measured in the first direction, between about 0.2 micrometer and about 5 micrometers and comprises an n-type dopant concentration between about 5×10¹⁷ cm⁻³ and about 6×10¹⁹ cm³.

10. The photodiode device of claim 1, wherein the p-type layer has a thickness, measured in the first direction, between about 5 nanometers and about 100 nanometers and comprises a p-type dopant concentration between about 10¹⁸ cm⁻³ and about 10²¹ cm⁻³.

11. The photodiode device of claim 1, further comprising a lower cladding layer underlying the at least one multiple quantum well layer, the lower cladding layer having a thickness in the first direction between about 6 nanometers and about 14 nanometers, an n-type dopant concentration between about 1×10¹⁹ cm⁻³ and about 5×10¹⁹ cm⁻³, and comprising up to about 4 atomic % In.

12. The photodiode device of claim 1, further comprising an upper cladding layer overlying the upper barrier layer, the upper cladding layer having a thickness in the first direction between about 10 nanometers and about 30 nanometers, a p-type dopant concentration between about 8×10¹⁹ cm⁻³ and about 6×10²⁰ cm⁻³.

13. The photodiode device of claim 1, further comprising a strained-layer superlattice overlying the n-type layer, the strained-layer superlattice comprising between about 25 and about 80 alternating layers of AlInGaN, the alternating layers having a difference in In content of between about 0.5 atomic % and about 4 atomic % and a thickness between about 0.5 nanometer and about 3 nanometers.

14. The photodiode device of claim 1, further comprising a p-side reflective electrical contact, the p-side reflective electrical contact overlying the p-type layer and having an average reflectivity greater than 70% for angles between 0 and 20 degrees from the first direction at wavelengths between about 360 nanometers and about 500 nanometers.

15. The photodiode device of claim 14, wherein the p-side reflective electrical contact comprises at least a first layer and a second layer, the first layer comprising silver and having a thickness between about 1 nanometer and about 100 nanometers and the second layer comprising at least one of nickel, copper, cobalt, iron, and manganese and having a thickness between about 0.5 nanometer and about 2 nanometers.

16. The photodiode device of claim 15, wherein the p-side reflective electrical contact further comprises a third layer underlying the first layer, and the third layer comprising at least one of nickel and platinum and having a thickness between about 0.25 nanometer and about 3 nanometers.

17. The photodiode device of claim 1, further comprising a substrate having a backside surface and an upper surface, each of the at least one multiple quantum well layer, the n-type layer, the upper barrier layer, and the p-type layer overlying the upper surface, wherein:
the backside surface comprises a plurality of hexagonal shaped pyramid structures, each of the hexagonal shaped pyramid structures having a peak-to-peak height ranging from about 0.3 micrometer to about 30 micrometers, and a base dimension ranging from about 0.3 micrometer to about 30 micrometers, and having an irregularity in size ranging from 0% to 50%, and an interior region disposed between a pair of the plurality of hexagonal shaped pyramid structures.

18. The photodiode device of claim 17, further comprising a plurality of nanodot structures disposed overlying the interior region and overlying a portion of the hexagonal shaped pyramid structures and configured to direct electromagnetic radiation having a wavelength ranging from 360 to 500 nanometers to the absorber layer.

19. The photodiode device of claim 18, wherein the plurality of hexagonal shaped pyramid structures comprises between 50% and 100% of the backside surface area, wherein the surface area is measured in directions parallel to the upper surface.

20. The photodiode device of claim 18, wherein each of the substrate, the plurality of hexagonal-shaped pyramid structures, and the nanodot structures comprise gallium nitride.

21. A photodiode device, comprising:
a die comprising at least one multiple quantum well layer disposed between an n-type layer and an upper barrier layer, with a p-type layer overlying the upper barrier layer, each of the at least one multiple quantum well layer, the n-type layer, the upper barrier layer, and p-type layer comprising AlₓIn_{y}Ga_{1-x-y}N, where 0≤x, y, x+y≤1 and having a dislocation density below about 10¹⁰ cm⁻² wherein
the at least one multiple quantum well layer comprises at least 25 pairs of a well layer and a barrier layer, the well layers having a thickness, measured in a first direction, between about 2 nanometers and about 5 nanometers, and the barrier layers having a thickness, also measured in a first direction, between about 0.5 nanometer and about 2.5 nanometers;
the p-type layer has a thickness, measured in the first direction, between 1 nanometer and 1000 nanometers;
the upper barrier layer has a thickness between about 4 nanometers and about 10 nanometers and comprises up to about 4 atomic percent of indium (In), expressed on a metals basis;
each of the at least one multiple quantum well layer, the n-type layer, the upper barrier layer, and p-type layer have a crystallographic orientation within 5 degrees of c-plane and are parallel to a first plane that is oriented normal to the first direction; the die is characterized by:
a fill factor (FF) that is at least 70% at room temperature and increases in value by at least 2% as a temperature of the die is increased from about 25 degrees Celsius to about 80 degrees Celsius;
an external quantum efficiency (EQE) that is at least 70% and increases in value by at least 1% as a temperature of the die is increased from about 25 degrees Celsius to about 80 degrees Celsius; and
a power conversion efficiency that is at least 50% at room temperature and increases in value by at least 2% as a temperature of the die is increased from about 25 degrees Celsius to about 80 degrees Celsius;
wherein each of the fill factor, external quantum efficiency, and power conversion efficiency are measured using light having a wavelength between 360 nanometers and 500 nanometers and a power between 0.1 watt and 10 watts.

22. The die of claim 21, wherein the die is characterized by:
a fill factor (FF) that is at least 75% at room temperature and increases in value by at least 3% as a temperature of the die is increased from about 25 degrees Celsius to about 80 degrees Celsius;
an external quantum efficiency (EQE) that is at least 75% and increases in value by at least 2% as a temperature of the die is increased from about 25 degrees Celsius to about 80 degrees Celsius; and
a power conversion efficiency that is at least 55% at room temperature and increases in value by at least 3% as a temperature of the die is increased from about 25 degrees Celsius to about 80 degrees Celsius.
